(19) United States
(12) Patent Application Publication
(10) Pub. No.: US 2008/0199783 A1
(43) Pub. Date: Aug. 21, 2008

(54) Double-Decker Pellicle-Mask Assembly

(75) Inventors: Shih-Ming Chang, Hsinchu (TW); Hung-Chang Hsieh, Hsin-Chu City (TW); Burn Jeng Lin, Hsin-Chu (TW)

Correspondence Address: David M. O'Dell;Attorney for Applicants, Haynes and Boone, LLP, 901 Main Street, Suite 3100, Dallas, TX, 75202-3789, US

(73) Assignee: TAIWAN SEMICONDUCTOR MANUFACTURING COMPANY, LTD., Hsin-Chu (TW)

(21) Appl. No.: 11/677,142

(22) Filed: Feb. 21, 2007

(51) Int. Cl. G03F 1/00

(52) U.S. Cl. 430/5

(57) ABSTRACT

A pellicle-mask assembly includes a mask substrate having an absorber pattern, and a hard pellicle held against movement with respect to the mask substrate by gas pressure.

### FIELD OF THE INVENTION

The present invention relates generally to photolithography techniques for integrated circuit fabrication and, more particularly, to pellicles which reduce the propagation of defects in integrated circuits by shielding a mask from particles during photolithography.

### BACKGROUND OF THE INVENTION

Various processing steps are used to fabricate integrated circuits on a semiconductor wafer. These steps include: deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

During the photolithography step of semiconductor production, light energy is applied through a mask onto the photoresist material previously deposited on the wafer to define circuit patterns which will be etched in a subsequent processing step to define the circuits on the wafer. Because these circuit patterns on the photoresist represent a two-dimensional configuration of the circuit to be fabricated on the wafer, minimization of particle generation and uniform application of the photoresist material to the wafer are very important. By minimizing or eliminating particle generation during photoresist application, the resolution of the circuit patterns, as well as circuit pattern density, is increased.

Masks must remain meticulously clean for the creation of perfect images during its many exposures to pattern a circuit pattern on a substrate. The mask may be easily damaged such as by dropping of the mask, the formation of scratches on the mask surface, electrostatic discharge (ESD), and particles. ESD can cause discharge of a small current through the chromium lines on the surface of the mask, melting a circuit line and destroying the circuit pattern. Therefore, a pellicle is typically attached to a mask to prevent particles from accumulating on the mask.

Pellicles are necessary to prevent the propagation of particle-related defects in semiconductor device components during the use of steppers and scanners. The pellicle includes a membrane which covers the mask to keep unwanted particles safely out of focus from the patterned side of the mask. Particles which land on the pellicle or on the other side of the mask only contribute slightly to the patterning process, because they are far away from the object plane of the imaging system.

Generally, two different types of pellicles are used in semiconductor fabrication: soft pellicles and hard pellicles. Soft pellicles, which are easy to manufacture and handle, are fabricated by dropping an organic solution onto a high-speed spinning device to form a membrane. This membrane will be attached to a rigid frame, which in turn is attached to a mask. Soft pellicles are used for 193 nm or longer wavelength exposures. For wavelengths shorter than 193 nm, the existing materials used for soft pellicles are not suitable. These materials decay within hundreds of laser illumination exposures. Moreover, soft pellicles are typically discarded after use with just one mask, and are not reused with other masks.

FIGS. 1 and 2 illustrate a mask 8 on which is mounted a conventional soft pellicle 10. The mask 8 includes an absorber pattern 16 which is provided on a transparent substrate 14 such as quartz and defines the circuit pattern image to be transferred to a photolithography layer (not shown) on a wafer. The pellicle 10 includes a pellicle frame 12 which is attached to the substrate 14 and surrounds the absorber pattern 16. A transparent pellicle film 13 spans the pellicle frame 12 and extends over the absorber pattern 16. An air cavity 17 is defined between the pellicle film 13, the pellicle frame 12, and the substrate 14.

FIGS. 3 and 4 illustrate a mask 18 on which is mounted a conventional hard pellicle 20. The mask 18 includes an absorber pattern 26 provided on a transparent substrate 24 such as quartz. The pellicle 20 includes a pellicle frame 22 which is attached to the substrate 24 and surrounds the absorber pattern 26. The pellicle 20 is mounted on the pellicle frame 22 and extends over the absorber pattern 26. An air cavity 27 is defined between the pellicle 20, the pellicle frame 22, and the substrate 24.

Hard pellicles are difficult to manufacture and to mount on a flat planar surface of a mask. For an ordinary 150-mm(6 inch) mask, a hard pellicle includes a transparent plate having a length of 140 mm, a width of 120 mm and a thickness on the order of 1 mm. Because of its non-negligible thickness, the hard pellicle is considered an optical element. Therefore, its smoothness and flatness must be kept within a fraction of the exposure wavelength. Moreover, the pellicle tilt must be within optical limits. Because of these strict requirements, hard pellicles are very expensive. In some extreme cases, a high-quality hard pellicle is more expensive than the mask to which the pellicle is attached.

Another drawback of hard pellicles is their fragility. Hard pellicles suffer distortion on the order of 4 □m(10⁻⁶ m) from center to edges when attached to a mask. Furthermore, hard pellicles are easy to damage during the mounting and dismounting processes. This is especially true of relatively thin hard pellicles, which are usually too fragile to survive the dismounting process.

Therefore, a mask-pellicle assembly is needed which is characterized by enhanced durability and less susceptibility to distortion after mounting to a mask.

An object of the present invention is to provide a novel pellicle-mask assembly which is durable.

Another object of the present invention is to provide a novel pellicle-mask assembly which is low-cost.

Still another object of the present invention is to provide a novel pellicle-mask assembly which is resistant to distortion.

Yet another object of the present invention is to provide a novel pellicle-mask assembly which does not require glue or other adhesives for mounting.

A still further object of the present invention is to provide a pellicle-mask assembly which is recyclable.

### SUMMARY OF THE INVENTION

One broad form of the invention involves providing an apparatus having first and second portions that respectively include a pellicle and a mask, and holding these portions against relative movement using external fluid pressure.

### BRIEF DESCRIPTION OF THE DRAWINGS

The invention will now be described, by way of example, with reference to the accompanying drawings, in which:

FIGS. 1 and 2 are top and sectional views, respectively, of a typical conventional pellicle-mask assembly;

FIGS. 3 and 4 are top and sectional views, respectively, of another conventional pellicle-mask assembly;

FIGS. 5 and 6 are top and sectional views, respectively, of a pellicle-mask assembly according to a first embodiment of the present invention;

FIGS. 7 and 8 are top and sectional views, respectively, of a pellicle-mask assembly according to a second embodiment of the present invention;

FIGS. 9 and 10 are top and sectional views, respectively, of a pellicle-mask assembly according to a third embodiment of the invention, which is a variation of the second embodiment shown in FIGS. 7 and 8;

FIG. 11 is a cross-sectional view of a pellicle-mask assembly according to a fourth embodiment of the present invention;

FIG. 12 is a cross-sectional view of a pellicle-mask assembly according to a fifth embodiment of the present invention;

FIGS. 13 and 14 are top and sectional views, respectively, of a pellicle-mask assembly according to a sixth embodiment of the present invention;

FIG. 15 is a top view of a pellicle-mask assembly according to a seventh embodiment of the present invention;

FIGS. 16 and 17 are top and sectional views, respectively, of a pellicle-mask assembly according to an eighth embodiment of the present invention;

FIG. 18 is a sectional view of a pellicle-mask assembly according to a ninth embodiment of the present invention;

FIG. 19 is a top view of a pellicle-mask assembly according to a tenth embodiment of the present invention; and

FIG. 20 is a sectional view of the pellicle-mask assembly shown in FIG. 19.

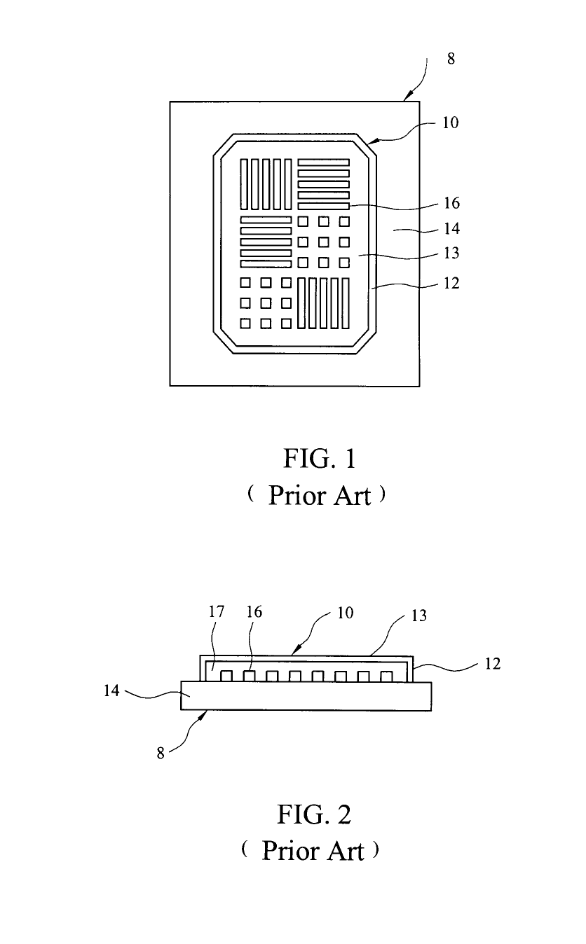

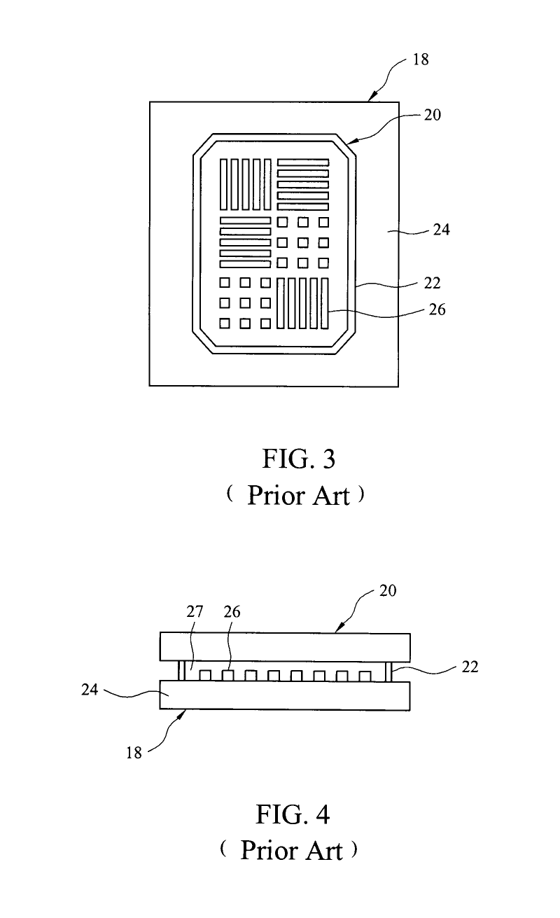

### DETAILED DESCRIPTION OF THE INVENTION

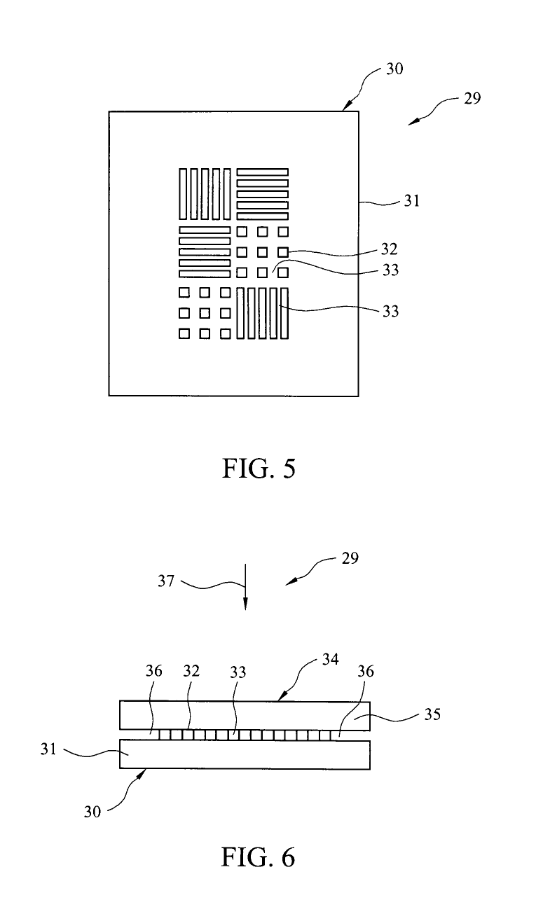

Referring initially to FIGS. 5 and 6, a first embodiment of a pellicle-mask assembly of the present invention is generally indicated by reference numeral 29. The pellicle-mask assembly 29 includes a mask 30 having a transparent substrate 31 which may be quartz, for example. An absorber pattern and/or phase-shift pattern 32 is formed on the surface of the substrate 31 using techniques known by those skilled in the art. In fabrication of the pellicle-mask assembly 29, a hard pellicle 34, having a transparent pellicle body 35 such as quartz, is secured against the absorber pattern 32. In this regard, the assembly 29 does not have any structure that physically connects the pellicle body 35 and the mask substrate 31 so that they are not able to move relative to each other. Instead, they are coupled through use of a vacuum.

More specifically, the hard pellicle 34 is preferably a relatively thick hard pellicle, with a thickness of at least about 1 mm. Accordingly, attachment of the hard pellicle 34 to the mask 30 may be carried out in a conventional vacuum chamber (not shown). In the fabricated pellicle-mask assembly 29, vacuum spaces 33 exist between the substrate 31 and the pellicle body 35 in the interstices defined by the absorber pattern 32, whereas air spaces 36 are defined between the substrate 31 and the pellicle body 35 at the edges of the absorber pattern 32. Therefore, the absorber pattern 32 abuts against the pellicle body 35 to form a seal which contains the vacuum in the vacuum spaces 33. Atmospheric air provides a fluid pressure that presses against the pellicle body 35 and mask substrate 31 and thus urges them together so as to fixedly couple them together and maintain the structural integrity of the pellicle-mask assembly 29.

In use of the pellicle-mask assembly 29, the assembly 29 is placed on a mask stage in a scanner (not shown) or stepper (not shown). UV light 37 is directed through the pellicle 34, absorber pattern 32 and mask substrate 31, respectively, and onto the surface of a photoresist layer (not shown) provided on a wafer. The UV light 37 transfers the circuit pattern image defined by the absorber pattern 32 onto the photoresist layer, which is then developed to define the circuit pattern image that is to be etched into an underlying layer, as is known by those skilled in the art.

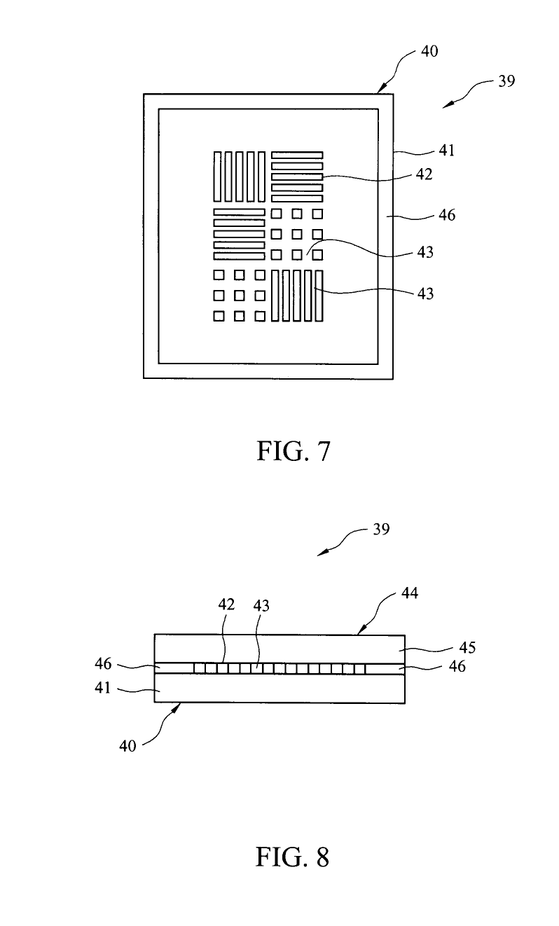

Referring next to FIGS. 7-10, a second embodiment of a pellicle-mask assembly of the present invention is generally indicated by reference numeral 39 and includes a mask 40 having a transparent substrate 41 and an absorber pattern and/or phase-shift pattern 42 on the surface of the substrate 41. In fabrication of the pellicle mask assembly 39, a hard pellicle 44, having a transparent pellicle body 45, is secured against the absorber pattern 42 using a vacuum, and this step may be carried out in a conventional vacuum chamber (not shown). In the fabricated pellicle-mask assembly 39, vacuum spaces 43 exist between the mask substrate 41 and the pellicle body 45 in the interstices defined by the absorber pattern 42. A sealing frame 46, which may be plastic, for example, is interposed between and sealingly engages the mask substrate 41 and the pellicle body 45 along the edges or perimeter of the absorber pattern 42. Atmospheric air pressure urges the pellicle 44 against the mask 40 so as to fixedly couple them, due to the vacuum in the vacuum spaces 43.

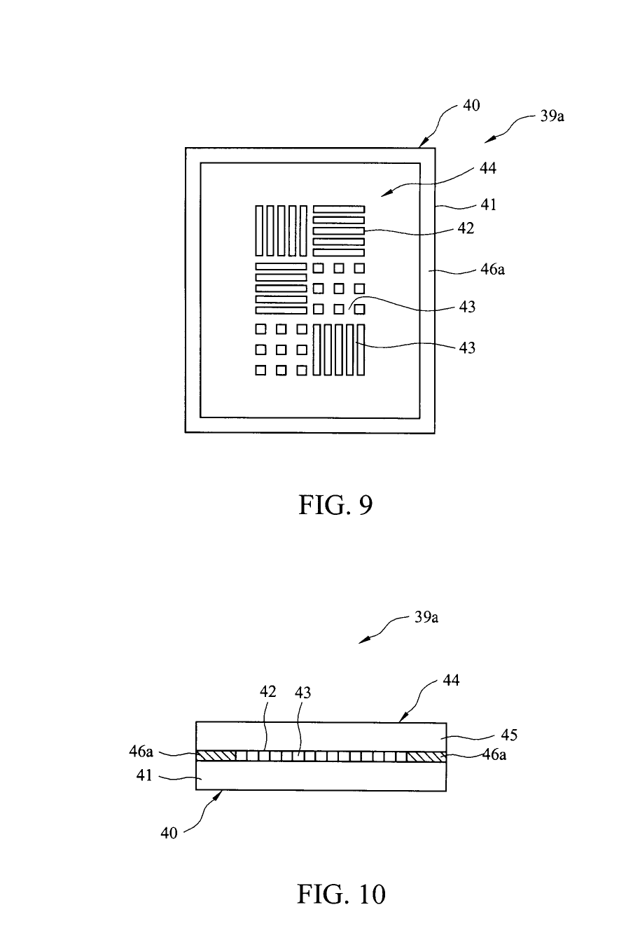

Referring next to FIGS. 9-10, a third embodiment of a pellicle-mask assembly of the present invention is generally indicated by reference numeral 39a. The pellicle-mask assembly 39a in FIG. 9 is similar to the pellicle-mask assembly 39 of FIGS. 7-8, except that the sealing frame 46a is made of rubber. Another alternative material for the sealing frame 46 is an oxide.

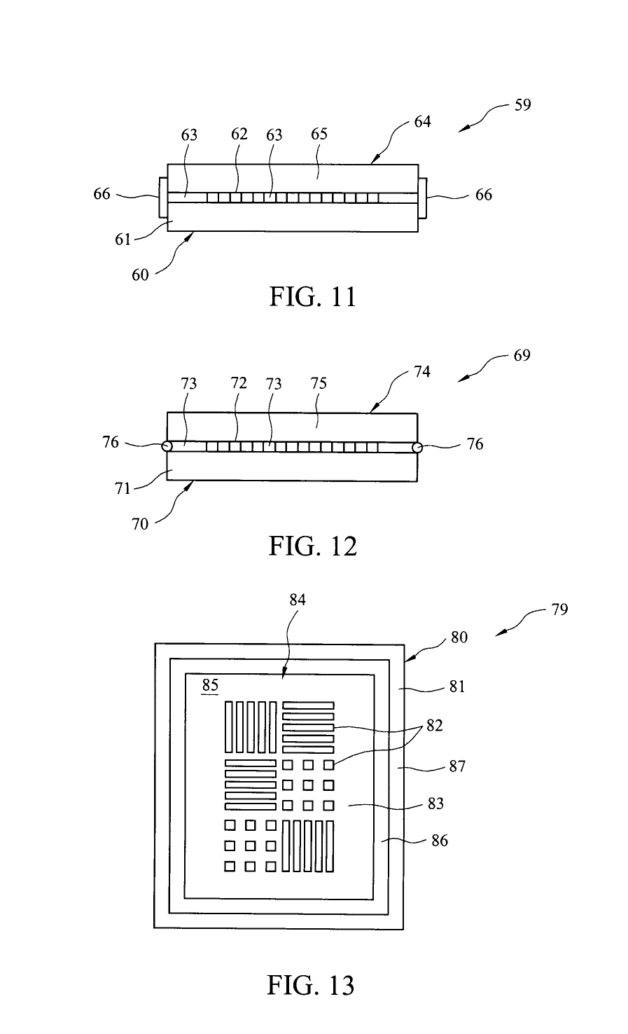

Referring next to FIG. 11, a fourth embodiment of a pellicle-mask assembly of the present invention is generally indicated by reference numeral 59 and includes a mask 60 having a transparent substrate 61 and an absorber pattern and/or phase shift pattern 62 on the surface of the substrate 61. A hard pellicle 64, having a transparent pellicle body 65, is secured against the absorber pattern 62 using a vacuum. Vacuum spaces 63 exist in the interstices defined by the absorber pattern 62 and at the edges or perimeter of the absorber pattern 62. A flat O-ring 66, which may be rubber or plastic, for example, is provided along the edges of the pellicle-mask assembly 59, and tightly engages the edges of the mask substrate 61 and pellicle body 65. Atmospheric air pressure, in conjunction with the vacuum in the vacuum spaces 63, secures the pellicle 64 to the mask 60. The O-ring 66 prevents air from entering between the mask substrate 61 and pellicle body 65, thus maintaining the integrity of the vacuum pressure in the vacuum spaces 63.

Referring next to FIG. 12, a fifth embodiment of a pellicle-mask assembly 69 of the present invention includes a mask 70 having a transparent substrate 71 and an absorber pattern 72. A hard pellicle 74, having a transparent pellicle body 75, is secured against the absorber pattern 72 by a vacuum and atmospheric air pressure. Vacuum spaces 73 are defined by the interstices in the absorber pattern 72 and at the edges of the absorber pattern 72. A round O-ring 76, which may be rubber or plastic, for example, is provided along the edges of the pellicle-mask assembly 69. The round O-ring 76 engages the mask substrate 71 and pellicle body 75. The O-ring 76 prevents air from entering between the mask substrate 71 and pellicle body 75 and maintains the integrity of the vacuum in the vacuum spaces 73.

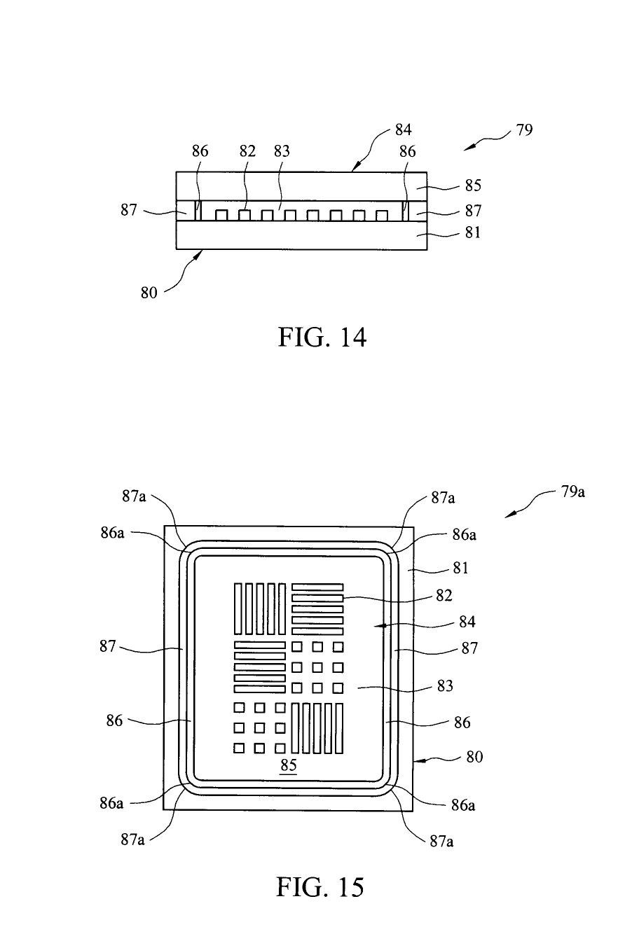

Referring next to FIGS. 13-14, a sixth embodiment of a pellicle-mask assembly of the present invention is generally indicated by reference numeral 79. The assembly 79 includes a mask 80 having a transparent substrate 81 and an absorber pattern and/or phase shift pattern 82. A hard pellicle 84, having a transparent pellicle body 85, is spaced from the absorber pattern 82 by a rigid inner support 86 and a soft or resilient outer frame 87 which surrounds the inner support 86. A vacuum space 83 is defined between the mask substrate 81 and the pellicle body 85. The vacuum space 83 is defined by assembling the mask substrate 81 and pellicle body 85 on the inner support 86 and outer frame 87 in a vacuum chamber (not shown). The inner support 86 and outer frame 87 prevent air from leaking into the vacuum space 83 from outside the pellicle-mask assembly 79, thereby maintaining the integrity of the vacuum pressure in the vacuum space 83. Atmospheric air pressure urges the mask 80 and pellicle 84 together, so as to fixedly couple them.

Referring next to FIG. 15 a seventh embodiment of a pellicle-mask assembly of the present invention is generally indicated by reference numeral 79a. The pellicle-mask assembly 79a is similar to the pellicle-mask assembly 79 of FIGS. 13-14, except that the inner support 86 has rounded corners 86a and the outer frame 87 has rounded corners 87a.

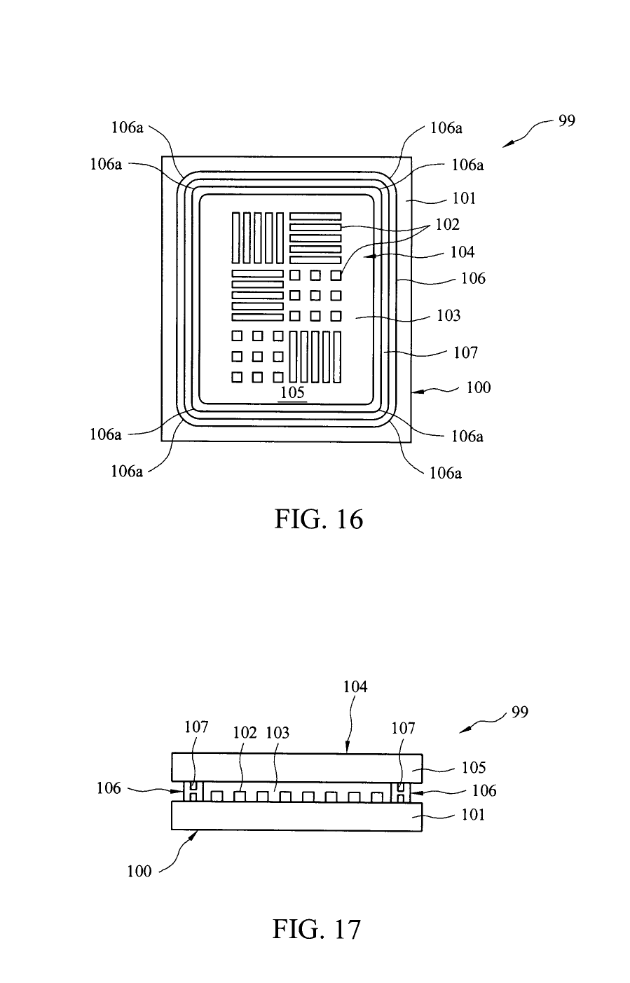

An eighth embodiment of a pellicle-mask assembly of the present invention is generally indicated by reference numeral 99 in FIGS. 16 and 17 and includes a mask 100 having a transparent substrate 101 and an absorber pattern 102 thereon. A hard pellicle 104 having a transparent pellicle body 105 is spaced from the absorber pattern 102 by a rigid support 106 which has two grooves in opposite sides thereof that give it a generally “H”-shaped cross-sectional configuration, as shown in FIG. 17. The support 106 extends around the perimeter of the absorber pattern 102. A seal ring of sealing material 107 is disposed in one groove and sealingly engages the rigid support 106 and the mask substrate 101, and a similar seal ring is disposed in the other groove and sealingly engages the rigid support 106 and the pellicle body 105. A vacuum space 103 is defined between the mask substrate 101 and the pellicle body 105. The vacuum space 103 is formed by assembling the mask substrate 101 and the pellicle body 105 on the rigid support 106 in a vacuum chamber (not shown). The rigid support 106 prevents air from leaking into the vacuum space 103 from outside the pellicle-mask assembly 99, thereby maintaining the integrity of the vacuum seal in the vacuum space 103. Atmospheric air pressure urges the mask 100 and pellicle 104 together, so as to fixedly couple them.

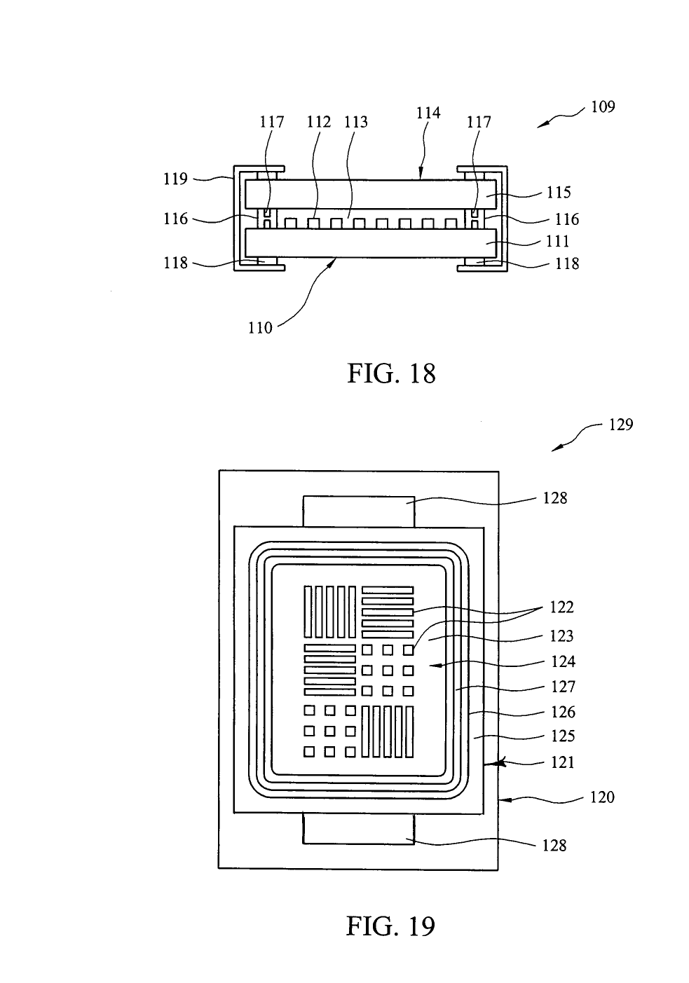

Referring next to FIG. 18, a ninth embodiment of a pellicle-mask assembly of the present invention is generally indicated by reference numeral 109 and includes a mask 110 having a transparent substrate 111 and an absorber pattern 112 provided thereon. A hard pellicle 114 having a transparent pellicle body 115 is spaced from the absorber pattern 112 by a rigid support 116 having two grooves that give it a generally “H”-shaped cross-sectional configuration. A seal ring 117 is disposed in one groove and sealingly engages the rigid support 116 and the mask substrate 111, and a similar seal ring 117 is disposed in the other groove and sealingly engages the rigid support 116 and the pellicle body 115. The pellicle-mask assembly 109 is assembled in a vacuum chamber (not shown) to form a vacuum space 113 between the mask substrate 111 and the pellicle body 115. Two mechanical support brackets 119, which each have a generally “C”-shaped configuration, each engage outer sides of the mask substrate 111 and the pellicle body 115. A respective resilient pad 118 is interposed between the pellicle body 115 and the upper segment of each mechanical support bracket 119 and between the mask substrate 111 and the lower segment of each mechanical support bracket 119. The rigid supports 116, seal rings 117 and mechanical support brackets 119 prevent air from leaking into the vacuum space 113 from outside the pellicle-mask assembly 109, thereby maintaining the integrity of the vacuum seal in the vacuum space 113. With the rigid support 116, the gas pressure in the space 113 could alternatively be larger than the outside air pressure.

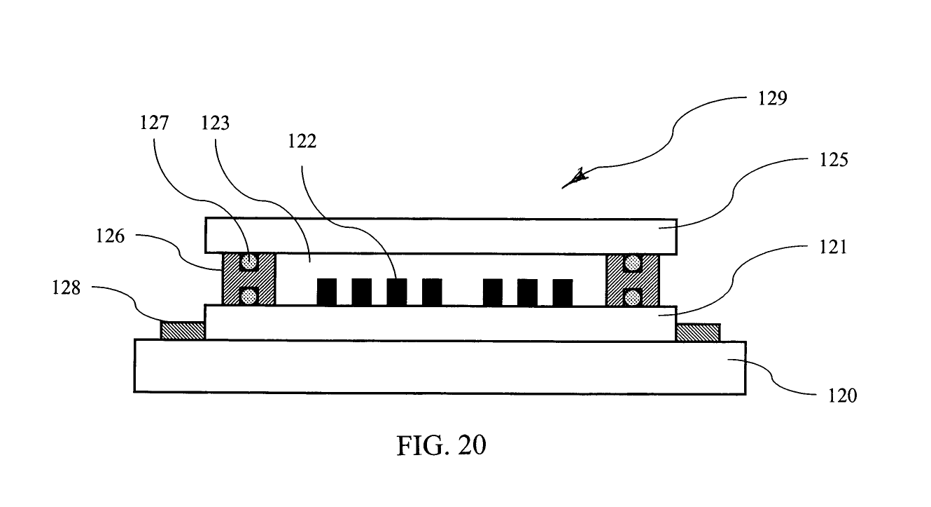

A top view of a tenth embodiment of the pellicle-mask assembly of the present invention is generally indicated by reference numeral 129 in FIGS. 19 and 20. The assembly 129 includes a mask stage 120 with two spaced safety stops 128 thereon. A transparent mask 121 is provided on the mask stage 120, and an absorber pattern 122 is provided on the mask 121. A hard pellicle 124 having a transparent pellicle body 125 is spaced from the absorber pattern 122 by a rigid support 126 which has two grooves that give it a generally “H”-shaped cross-sectional configuration, as heretofore described with respect to the rigid support 116 of FIG. 18. A seal ring 127 is disposed in one of the two grooves and sealingly engages the rigid support 126 and the mask 121, and a similar seal ring is disposed in the other groove and sealingly engages the rigid support 126 and the pellicle body 125. The pellicle-mask assembly 129 is assembled in a vacuum chamber (not shown) to form a vacuum space 123 between the mask 121 and the pellicle body 125, in the same manner as heretofore described with respect to the vacuum space 113 of FIG. 18. The rigid support 126 and seal rings 127 prevent air from leaking into the vacuum space from outside the pellicle-mask assembly 129. The safety stops 128 protect the mask 121 from separating from the mask stage 120 when the assembly 129 is on a stepper or scanner stage (not shown) during a photolithography process.

Several embodiments of the invention have been described above. They each utilize a thick hard pellicle. Thick hard pellicles are stronger and more durable than soft pellicles and thin hard pellicles, are less likely to be damaged during mounting of the pellicle on a mask or dismounting of the pellicle from a mask, can be reused, and cost less. After attachment to a mask, they are less susceptible to distortion due to the force of gravity. In each of the disclosed embodiments, there is a vacuum space between the mask and pellicle, and the mask and pellicle are fixedly coupled to each other by atmospheric air pressure. This avoids the need for glue, while providing an adhesion force stronger than that of glue. The absence of glue effectively provides a zero mounting and dismounting force (ZMDF) that avoids pellicle damage and the need to remove glue residue during mounting and dismounting, thereby facilitating reuse of the hard pellicle with a different mask. The absence of glue also avoids pellicle tilt after mounting as a result of non-uniform glue thickness, and avoids problems caused by outgasing from glue. Some of the disclosed embodiments use a support between the mask and pellicle, which positions the pellicle further from the mask and thus reduces the optical effect of any particles that may collect on the pellicle.

While several selected embodiments of the invention have been described above, it will be recognized and understood that various modifications can be made in the invention, and the appended claims are intended to cover all such modifications which may fall within the spirit and scope of the invention.

What is claimed is:

1. A pellicle-mask assembly comprising:
a mask substrate having an absorber pattern; and
a hard pellicle in contact with said mask substrate, said assembly being free of physical structure that holds said mask substrate and said hard pellicle against any relative movement, said mask substrate and said hard pellicle being urged together by fluid pressure external to said assembly in a manner that holds said mask substrate and said hard pellicle against relative movement.

2. The pellicle-mask assembly of claim 1 wherein said fluid pressure is atmospheric pressure.

3. The pellicle-mask assembly of claim 1 wherein said hard pellicle has a thickness of at least about 1 mm.

4. The pellicle-mask assembly of claim 1 further comprising sealing means for sealing said hard pellicle with respect to said mask substrate to maintain a vacuum therebetween.

5. The pellicle-mask assembly of claim 4 wherein said sealing means includes said absorber pattern.

6. The pellicle-mask assembly of claim 4 wherein said sealing means includes a phase shift pattern.

7. The pellicle-mask assembly of claim 4 wherein said sealing means includes a continuous loop of sealing material.

8. The pellicle-mask assembly of claim 7 wherein said continuous loop of sealing material includes at least one material selected from the group consisting of rubber, plastic, oxide, said absorber pattern and a phase shift pattern.

9. A pellicle-mask assembly comprising:
a mask substrate having an absorber pattern; a hard pellicle attached to said mask substrate by gas pressure; and
a rigid support interposed between said mask substrate and said hard pellicle for maintaining vacuum pressure between said mask substrate and said hard pellicle.

10. The pellicle-mask assembly of claim 9 wherein said gas pressure is atmospheric pressure.

11. The pellicle-mask assembly of claim 9 wherein said hard pellicle has a thickness of at least about 1 mm.

12. The pellicle-mask assembly of claim 9 wherein said rigid support has a generally “H”-shaped cross-section.

13. The pellicle-mask assembly of claim 9 further comprising a sealing material interposed between said rigid support and said mask substrate and between said rigid support and said hard pellicle.

14. The pellicle-mask assembly of claim 13 further comprising a pair of mechanical support brackets engaging said mask substrate and said hard pellicle.

15. The pellicle-mask assembly of claim 9 wherein said rigid support includes a rigid inner support and further including a soft outer frame interposed between said mask substrate and said hard pellicle adjacent to said rigid inner support.

16. The pellicle-mask assembly of claim 9 further comprising a pair of safety stops carried by said hard pellicle.

17. A method of attaching a hard pellicle to a mask substrate, comprising:
providing a mask substrate having an absorber pattern;
providing a hard pellicle; and
retaining said hard pellicle against movement with respect to said mask substrate by maintaining a space between them at a pressure lower than atmospheric pressure.

18. The method of claim 17 wherein said attaching said hard pellicle to said mask substrate includes causing engagement of said hard pellicle with said absorber pattern, said space including vacuum spaces between portions of said absorber pattern.

19. The method of claim 17 further comprising providing a continuous sealing material between said mask substrate and said hard pellicle.

20. The method of claim 19 wherein said continuous sealing material includes a material selected from the group consisting of rubber, plastic and oxide.

21. An apparatus comprising an assembly having first and second portions that are physically separate, that engage each other but are free of physical structure holding said first and second portions against any relative movement, and that cooperate to define therebetween a closed chamber with a fluid pressure lower than a fluid pressure external to said assembly, said first and second portions being urged together by fluid pressure external to said assembly in a manner that holds said first and second portions against relative movement and that facilitates therebetween an annular fluid seal extending around said chamber, said first portion including a pellicle and said second portion including a mask.

22. An apparatus according to claim 21, wherein said apparatus includes an annular portion that sealingly engages each of said first and second portions along respective annular surface portions that extend around said chamber.

23. An apparatus according to claim 21, wherein said second portion includes an annular portion that extends around said chamber and a further portion that includes said mask, said further portion and said annular portion being physically separate, engaging each other but being free of physical interconnection, and each defining part of said chamber, said further portion and said annular portion being urged together by fluid pressure external to said assembly in a manner that holds said further portion and said annular portion against relative movement and that facilitates therebetween an annular fluid seal extending around said chamber.

24. An apparatus according to claim 22, wherein said annular portion includes an annular support having grooves in opposite sides thereof, and includes two annular seal elements that are each disposed in a respective said groove, said seal elements each sealingly engaging said support and a respective one of said first and further portions.
